(19) United States
(12) Patent Application Publication
(10) Pub. No.: US 2026/0262163 A1
(43) Pub. Date: Sep. 3, 2026

(54) PRINTED WIRING BOARD AND METHOD FOR MANUFACTURING THE SAME

(71) Applicant: IBIDEN CO., LTD., Gifu (JP)

(72) Inventors: Guanyu WU, Gifu (JP); Kazuyuki UEDA, Gifu (JP); Katsuyoshi YAMASAKI, Gifu (JP); Yoshifumi TANABE, Gifu (JP)

(73) Assignee: IBIDEN CO., LTD., Gifu (JP)

(21) Appl. No.: 19/549,244

(22) Filed: Feb. 25, 2026

(30) Foreign Application Priority Data
Feb. 28, 2025 (JP) 2025-030856

(51) Int. Cl. H05K 1/09

(52) U.S. Cl. CPC H05K 1/09; H05K 2201/032; H05K 2201/10234; H05K 2201/2081

(57) ABSTRACT

A printed wiring board includes an outermost resin insulating layer, a conductor layer formed on the outermost resin insulating layer, a solder resist layer formed on the outermost resin insulating layer such that the solder resist layer is covering the conductor layer, a Ni layer formed on a surface of a portion of the conductor layer such that the solder resist layer has an opening exposing the portion of the conductor layer, an alloy layer formed on a surface of the Ni layer such that the alloy layer is positioned in the opening formed in the solder resist layer, and a solder bump layer formed on a surface of the alloy layer such that the solder bump layer includes an Sn-Pd alloy having a Pd content of 0.5 at% or less.

### CROSS-REFERENCE TO RELATED APPLICATIONS

The present application is based upon and claims the benefit of priority to Japanese Patent Application No. 2025-030856, filed February 28, 2025, the entire contents of which are incorporated herein by reference.

### BACKGROUND OF THE INVENTION

### Field of the Invention

The present invention relates to a printed wiring board and a method for manufacturing the same. More specifically, the present invention relates to a printed wiring board having a palladium-containing alloy film and a method for manufacturing the same.

### Description of Background Art

Japanese Patent Application Laid-Open Publication No. 2006-114705 describes a printed wiring board having a solder pad structure. The entire contents of this publication are incorporated herein by reference.

### SUMMARY OF THE INVENTION

According to one aspect of the present invention, a printed wiring board includes an outermost resin insulating layer, a conductor layer formed on the outermost resin insulating layer, a solder resist layer formed on the outermost resin insulating layer such that the solder resist layer is covering the conductor layer, a Ni layer formed on a surface of a portion of the conductor layer such that the solder resist layer has an opening exposing the portion of the conductor layer, an alloy layer formed on a surface of the Ni layer such that the alloy layer is positioned in the opening formed in the solder resist layer, and a solder bump layer formed on a surface of the alloy layer such that the solder bump layer includes an Sn-Pd alloy having a Pd content of 0.5 at% or less.

According to another aspect of the present invention, a method for manufacturing a printed wiring board includes forming an outermost resin insulating layer, forming a conductor layer on the outermost resin insulating layer, forming a solder resist layer on the outermost resin insulating layer such that the solder resist layer covers the conductor layer, forming an opening in the solder resist layer such that the opening exposes a portion of the conductor layer, forming a Ni layer on a surface of the portion of the conductor layer such that the Ni layer is positioned in the opening formed in the solder resist layer, forming a Pd layer on a surface of the Ni layer such that the Pd layer is positioned in the opening formed in the solder resist layer, and forming a solder bump layer on a surface of an alloy layer such that the solder bump layer includes an Sn-Pd alloy having a Pd content of 0.5 at% or less. The forming the solder bump layer includes forming a solder paste layer on a composite layer including the Ni layer and the Pd layer and reflowing the solder paste layer formed on the composite layer such that Pd in the Pd layer diffuses into the solder paste layer and that the solder bump layer including the Sn-Pd alloy having the Pd content of 0.5 at% or less is formed on the surface of the alloy layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view for describing a printed wiring board according to an embodiment of the present invention;

FIG. 1B is a cross-sectional view for describing a printed wiring board according to an embodiment of the present invention;

FIG. 2A is a cross-sectional view for describing a method for manufacturing a printed wiring board according to an embodiment of the present invention;

FIG. 2B is a cross-sectional view for describing a method for manufacturing a printed wiring board according to an embodiment of the present invention;

FIG. 2C is a cross-sectional view for describing a method for manufacturing a printed wiring board according to an embodiment of the present invention;

FIG. 2D is a cross-sectional view for describing a method for manufacturing a printed wiring board according to an embodiment of the present invention;

FIG. 2E is a cross-sectional view for describing a method for manufacturing a printed wiring board according to an embodiment of the present invention;

FIG. 2F is a cross-sectional view for describing a method for manufacturing a printed wiring board according to an embodiment of the present invention;

FIG. 2G is a cross-sectional view for describing a method for manufacturing a printed wiring board according to an embodiment of the present invention;

FIG. 2H is a cross-sectional view for describing a method for manufacturing a printed wiring board according to an embodiment of the present invention; and

FIGS. 3A and 3B are cross-sectional views for describing an example of a conventional method for manufacturing a printed wiring board.

### DETAILED DESCRIPTION OF THE EMBODIMENTS

Embodiments will now be described with reference to the accompanying drawings, wherein like reference numerals designate corresponding or identical elements throughout the various drawings.

### Printed Wiring Board

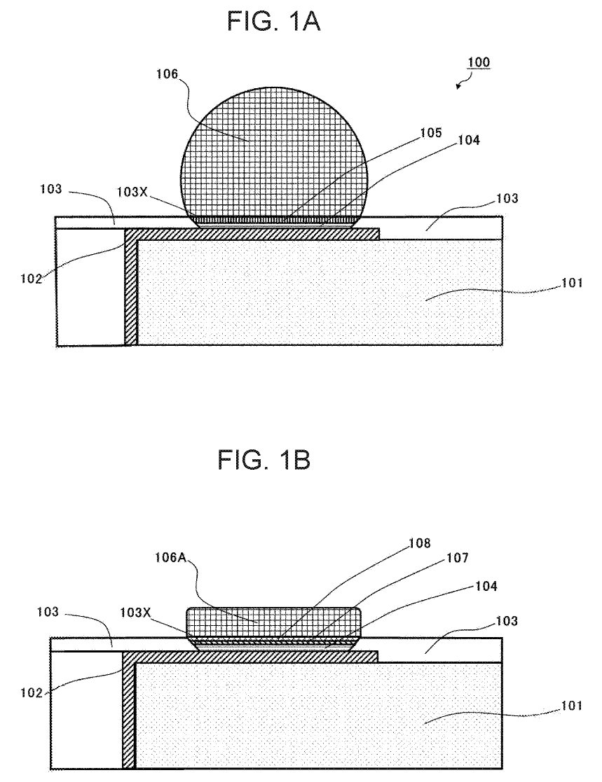

FIGS. 1A and 1B are cross-sectional views for describing a printed wiring board according to an embodiment of the present invention. In FIG. 1A, a printed wiring board 100 may be a substrate with a core, formed by alternately laminating predetermined resin insulation layers 101 and conductor layers 102 having circuit patterns on one side or both sides of a core substrate (not illustrated). When the conductor layers 102 are formed on both sides of the core substrate, the conductor layers facing each other across the core substrate may be connected via through-hole conductors (not illustrated). Further, the printed wiring board 100 may be a coreless substrate formed by alternately laminating the resin insulating layers 101 and the conductor layers 102 on a support plate (not illustrated) in place of the core substrate, and then removing the support plate.

As illustrated in FIG. 1A, the printed wiring board 100 includes a resin insulating layer 101 positioned as an outermost layer among at least one resin insulating layer, and a conductor layer 102 having a predetermined pattern formed on the resin insulating layer 101. In the printed wiring board 100 illustrated in FIG. 1, multiple other conductor layers 102 and resin insulating layers 101 are often alternately provided below the resin insulating layer 101, but these are omitted in the drawing.

The resin insulating layer 101 may be formed containing inorganic particles and an insulating resin. The inorganic particles may be an inorganic filler formed of silica, alumina, talc, barium sulfate, titanium oxide, zinc oxide, and the like. Such insulating resin may be an epoxy resin, a polyimide resin, or a phenol resin. The conductor layer 102 is formed on a surface of the resin insulating layer 101. The conductor layer 102 is composed of a seed layer formed of a metal thin film and a metal plating film formed on the seed layer. The seed layer may be formed of an electroless copper plating film. The metal plating film may be formed of, for example, an electrolytic copper plating film. The conductor layer 102 includes conductor circuits, via conductors, and the like.

The printed wiring board 100 includes a solder resist layer 103 formed so as to cover the resin insulating layer 101 positioned as an outermost layer and the conductor layer 102 formed on the resin insulating layer 101. In the solder resist layer 103, solder resist layer openings (103X) are formed that reach an upper surface of the conductor layer 102 positioned as an outermost layer. The conductor layer 102 provided in the printed wiring board 100 is exposed from the solder resist layer openings (103X) formed in the solder resist layer 103. The solder resist layer 103 may contain an alkali-soluble resin, a polyfunctional acrylic monomer, a photopolymerization initiator, an epoxy resin, an inorganic filler, and the like. The solder resist layer 103 may optionally contain dyes and pigments such as phthalocyanine green. The solder resist layer 103 preferably has a thickness of 4 to 40 μm from a viewpoint of functionality and processability.

The solder resist layer openings (103X) expose the conductor layer 102 formed on the surface of the resin insulation layer 101 and each have a recessed shape for forming a solder bump layer 106 via a Ni layer 104 and an alloy layer 105 formed on the surface of the exposed conductor layer 102. The recessed shape of the solder resist layer openings (103X) can be appropriately set according to a thickness of the Ni layer 104, a thickness of the alloy layer 105, and a size of the solder bump layer 106.

The printed wiring board 100 has the Ni layer 104 on the surface of the conductor layer 102 that is exposed from the solder resist layer openings (103X). The Ni layer 104 may be composed solely of Ni, or may be composed of a Ni-containing alloy such as Ni-Cu alloy, Ni-P alloy, or Ni-Cu-P alloy. Among these, the Ni layer 104 is preferably composed of Ni-P alloy or Ni-Cu-P alloy. The reason for this is that, even when unevenness is formed on the surface of the conductor layer 102 of the printed wiring board 100, such unevenness can be offset, and a conductor layer 102 having a film with a flattened surface layer can be formed. The Ni layer 104 preferably has a thickness of 1.5 to 3.0 μm.

Further, the printed wiring board 100 has the alloy layer 105 formed on a surface of the Ni layer 104. The alloy layer 105 is formed at an interface between the Ni layer 104 and the solder bump layer 106, and improves bonding strength between the Ni layer 104 and the solder bump layer 106. That is, the alloy layer 105 can improve rigidity against tensile forces at the interface between the Ni layer 104 and the solder bump layer 106. As a result, peel strength at the interface between the Ni layer 104 and the solder bump layer 106 can be improved. The alloy layer 105 may contain, for example, Ni-Sn alloy, Cu-Ni-Sn alloy, Ag-Ni-Sn alloy, or the like.

By setting the thickness of the alloy layer 105 within a predetermined range, bonding strength at the interface between the Ni layer 104 and the solder bump layer 106 can be further enhanced, and tensile strength at the interface between the Ni layer 104 and the solder bump layer 106 can be further improved.

The alloy layer 105 preferably has a thickness of 1.0 to 2.5 μm. By setting the thickness of the alloy layer 105 within such a range, the rigidity of the alloy layer 105 can be increased, and the tensile strength or the like at the interface between the Ni layer 104 and the solder bump layer 106 can be improved.

As illustrated in FIG. 1B, the alloy layer 105 is produced by reflowing a composite layer that includes a Ni layer 104 and a Pd layer 107 formed in a manufacturing process in a method for manufacturing a printed wiring board described below, or a composite layer that includes a Ni layer 104, a Pd layer 107, and a corrosion-resistant layer 108 made of a noble metal such as Au. Pd contained in the Pd layer 107, Au contained in the corrosion-resistant layer 108, and the like, which constitute the composite layer, diffuse into the solder bump layer 106 by reflow.

Therefore, at the interface between the Ni layer 104 and the solder bump layer 106, an alloy layer 105 made of an alloy containing Ni, which is the main component of the Ni layer 104, and Sn, which is the main component of the solder bump layer 106, is formed. The Pd layer 107 preferably has a thickness of 0.01 to 0.03 μm.

The printed wiring board 100 includes the solder bump layer 106 formed on the surface of the alloy layer 105. The solder bump layer 106 is formed on the surface of the conductor layer 102, which is exposed from the solder resist layer openings (103X), via the Ni layer 104 and the alloy layer 105.

The solder bump layer 106 is made of a metal having a low melting point that melts during reflow processing and is formed from a spherical shape into a substantially hemispherical shape, for example, a metal containing tin (Sn) as a main component. Specifically, the solder bump layer 106 may be composed of a binary solder, a ternary solder, a quaternary solder, or the like.

Examples of binary solders constituting the solder bump layer 106 include tin (Sn)/copper (Cu), tin (Sn)/zinc (Zn), tin (Sn)/silver (Ag), tin (Sn)/lead (Pb), tin (Sn)/antimony (Sb), and the like.

Examples of ternary solders include tin (Sn)/silver (Ag)/copper (Cu), tin (Sn)/silver (Ag)/lead (Pb), tin (Sn)/silver (Ag)/antimony (Sb), tin (Sn)/lead (Pb)/copper (Cu), tin (Sn)/silver (Ag)/indium (In), tin (Sn)/antimony (Sb)/copper (Cu), and the like.

Examples of quaternary solders include tin (Sn)/silver (Ag)/copper (Cu)/antimony (Sb), tin (Sn)/silver (Ag)/copper (Cu)/bismuth (Bi), and the like.

The solder bump layer 106 provided in the printed wiring board 100 according to an embodiment of the present invention contains an Sn-Pd alloy having a Pd content of 0.5 at% or less. That is, the solder bump layer 106 contains an Sn-Pd alloy, and the Sn-Pd alloy contains Pd. The solder bump layer 106 preferably has a Pd content of 0.01 at% or more and 0.5 at% or less.

A Pd content of 0.01 at% or more in the solder bump layer 106 is preferable because it promotes the formation of the alloy layer 105. A Pd content of 0.5 at% or less in the solder bump layer 106 is preferable because Pd atoms diffuse uniformly without segregating inside the solder bump layer 106. By allowing Pd atoms to diffuse uniformly without segregating inside the solder bump layer 106, a solder paste layer (106A) can be uniformly melted, and the surface shape of the solder bump layer 106 can be made spherical after reflowing the solder paste.

Thus, in the printed wiring board 100 according to an embodiment of the present invention, by setting the Pd content in the solder bump layer 106 to 0.5 at% or less, a predetermined amount of Pd atoms is uniformly diffused inside the solder paste layer (106A). As a result, the printed wiring board 100 according to an embodiment of the present invention has a substantially spherical solder bump layer 106 due to the uniform melting of the solder paste layer (106A).

The solder bump layer 106 provided in the printed wiring board 100 according to an embodiment of the present invention constitutes an outermost surface of the printed wiring board 100. That is, the solder bump layer 106 is used for connection between the printed wiring board 100 and an external semiconductor element. That is, the outermost surface of the printed wiring board 100 on which the solder bump layer 106 is formed serves as an electronic component mounting surface to which an external semiconductor element is connected. Examples of the semiconductor element mounted on the printed wiring board 100 include a semiconductor chip, a semiconductor integrated circuit, a transistor, and the like.

### Method for Manufacturing Printed Wiring Board

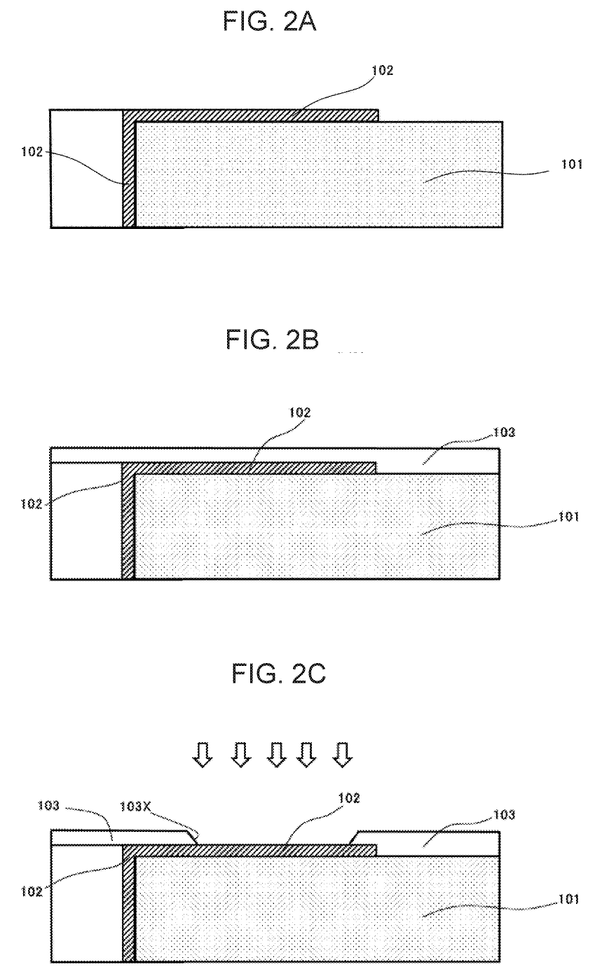

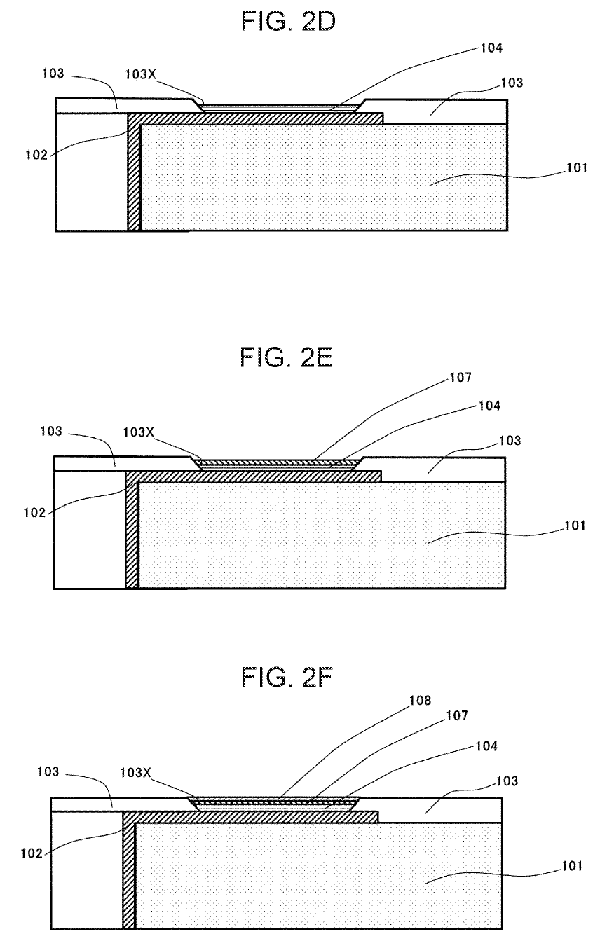

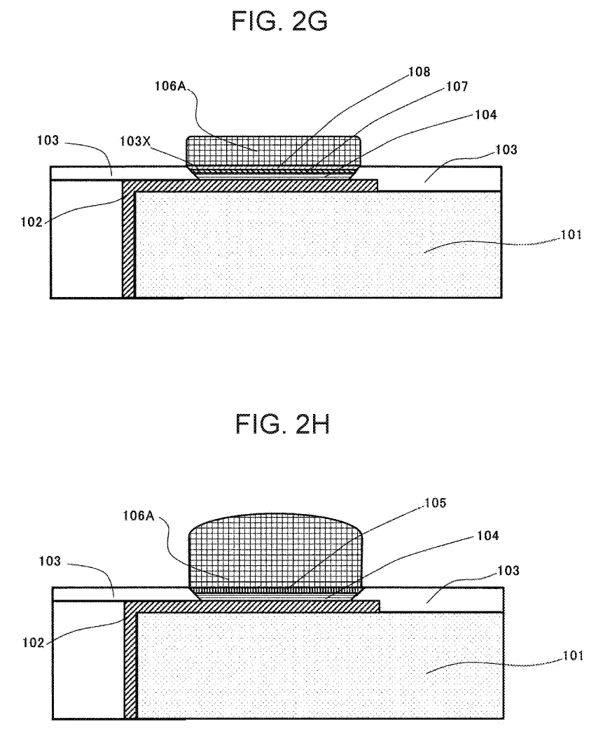

FIGS. 2A to 2H are cross-sectional views for describing a method for manufacturing a printed wiring board according to an embodiment of the present invention.

As illustrated in FIG. 2A, the conductor layer 102 is formed on the resin insulating layer 101 positioned as the outermost layer of the printed wiring board 100. The conductor layer 102 can be formed on the resin insulating layer 101, for example, using a subtractive method.

After forming the conductor layer 102 on the resin insulating layer 101, a roughened layer (not illustrated) may be provided on the conductor layer 102. Providing a roughened layer on the conductor layer 102 is preferable because it can ensure adhesion between the conductor layer 102 and the solder resist layer 103.

As illustrated in FIG. 2B, the solder resist layer 103 is formed so as to cover the resin insulating layer 101 and the conductor layer 102.

The solder resist layer 103 may be formed by applying a commercially available solder resist composition at a predetermined thickness onto the upper surface of the resin insulating layer 101 positioned as an uppermost layer and onto the conductor layer 102, and then drying the solder resist composition.

As illustrated in FIG. 2C, the solder resist layer openings (103X) are formed in the solder resist layer 103 to expose the conductor layer 102. By exposing the conductor layer 102 from the solder resist layer openings (103X), a conductor layer surface is exposed. The solder resist layer openings (103X) are formed so as to reach the conductor layer 102 formed on the resin insulating layer 101.

The solder resist layer openings (103X) may be formed by bringing a photomask (not illustrated) on which opening patterns for solder bump formation have been drawn into close contact with the solder resist layer 103, exposing the solder resist layer 103 to ultraviolet light, and then performing development processing with a DMTG solution or the like. The solder resist layer openings (103X) may also be formed by laser processing.

As illustrated in FIG. 2D, the Ni layer 104 is formed on the conductor layer surface of the conductor layer 102. The forming of the Ni layer 104 on the conductor layer surface may be performed by immersing the conductor layer 102 in an electroless nickel plating solution and then drying it. The thickness of the Ni layer 104 can be appropriately set, and is preferably, for example, 1.5 to 3.0 μm.

By forming the Ni layer 104, even when a roughened layer has been provided on the conductor layer surface of the conductor layer 102, the uneven portion can be completely covered, and the adhesion between the solder resist layer 103 and the conductor layer 102 can be improved.

As illustrated in FIG. 2E, the Pd layer 107 is formed on a Ni layer surface of the Ni layer 104. The forming of the Pd layer 107 on the Ni layer surface may be performed by immersing the Ni layer 104 in an electroless palladium plating solution and then drying it. The Pd layer 107 preferably has a thickness of 0.01 to 0.03 μm. By setting the thickness of the Pd layer 107 to 0.01 to 0.03 μm, in the process of reflowing the composite layer including the Ni layer 104 and the Pd layer 107 together with the solder paste layer (106A), the solder paste layer (106A) can be uniformly melted as Pd atoms uniformly diffuse without segregation inside the solder bump layer 106. That is, by setting the thickness of the Pd layer 107 to 0.01 to 0.03 μm, palladium can be uniformly diffused into the solder paste layer (106A), the solder paste layer (106A) can be uniformly melted, the surface shape of the solder bump layer 106 can be made spherical, and solder bumps can be made uniform in height.

As illustrated in FIG. 2F, the corrosion-resistant layer 108 is formed on the surface of the Pd layer 107. The corrosion-resistant layer 108 is formed from the composite layer by reflow and has a role of promoting the formation of the alloy layer 105 formed on the Ni layer surface of the Ni layer 104. The corrosion-resistant layer 108 is preferably formed of at least one selected from noble metals such as Au, Ag, and Pt, or from Sn.

Further, the corrosion-resistant layer 108 may be formed by adopting displacement plating, electroless plating, two-stage plating constituted of displacement plating and electroless plating, or the like, using the same metal.

In this way, by forming the corrosion-resistant layer 108, the alloy layer 105 can be formed as a metal film that is not affected by the Ni layer 104 positioned below the alloy layer 105 formed from the composite layer, thereby suppressing degradation of the shape and function of the solder bump layer 106.

When the corrosion-resistant layer 108 is formed of an Au layer, the shape, corrosion resistance, function, and the like of the solder bump layer 106 can be controlled by a ratio of the Au layer in the composite layer.

Forming the corrosion-resistant layer 108 composed of gold or the like on the surface of the Pd layer 107 may be performed by immersing the Pd layer 107 in an electroless noble metal plating solution (for example, an electroless gold plating solution) and drying it. The corrosion-resistant layer 108 preferably has a thickness of 0.01 to 0.03 μm. By setting the thickness of the corrosion-resistant layer 108 to 0.01 to 0.03 μm, strength and corrosion resistance of the printed wiring board 100 obtained after reflow can be improved, and degradation of the shape and function of the solder bump layer 106 can be further suppressed.

As illustrated in FIG. 2G, the solder paste layer (106A) is formed on the surface of the corrosion-resistant layer 108. The solder paste layer (106A) may be formed on the surface of the corrosion-resistant layer 108 by printing solder paste onto the surface of the corrosion-resistant layer 108.

As illustrated in FIG. 2H, the composite layer including the Ni layer 104, the Pd layer 107, and the corrosion-resistant layer 108 is reflowed together with the solder paste layer (106A). The reflow may be performed under any conditions, for example, in a nitrogen atmosphere at 200 to 400 °C, preferably 250 to 350 °C, as long as the alloy layer 105 can be formed from the composite layer including the Ni layer 104, the Pd layer 107, and the corrosion-resistant layer 108, and the solder bump layer 106 can be formed from the solder paste layer (106A).

In a method for manufacturing a printed wiring board according to an embodiment of the present invention, the solder bump layer 106 is formed by reflowing the composite layer including the Ni layer 104, the Pd layer 107, and the corrosion-resistant layer 108 together with the solder paste layer (106A). Therefore, the solder bump layer 106 included in the printed wiring board 100 contains an Sn-Pd alloy, and the Pd content in the Sn-Pd alloy can be made 0.5 at% or less.

A method for manufacturing a printed wiring board according to an embodiment of the present invention provides a printed wiring board in which palladium is uniformly melted into the solder bump layer without segregation by reflow, and the solder bumps after the reflow have a uniform spherical surface shape and a uniform height.

A solder resist layer may be formed on an outermost layer of a printed wiring board in order to protect conductor circuits. When forming solder bumps on such a printed wiring board, solder pads are formed that are exposed by opening portions of the solder resist layer for connection to the conductor circuits. Solder bumps are formed by applying a nickel layer and a gold layer to the portions that will become the solder pads, printing solder paste thereon, and performing reflow.

However, when the solder pads have an opening diameter of 200 μm or less and solder paste is formed on the solder pads using printing, the solder bumps cannot maintain their shape due to insufficient filling or non-filling of solder on the solder pads, and may not be able to fulfill their function. Further, as the opening diameter of the solder pads becomes smaller, a connection area between the solder pads and the solder bumps becomes smaller, which may result in reduced adhesion between the solder pads and the solder bumps and degradation of electrical connectivity and reliability of the printed wiring board.

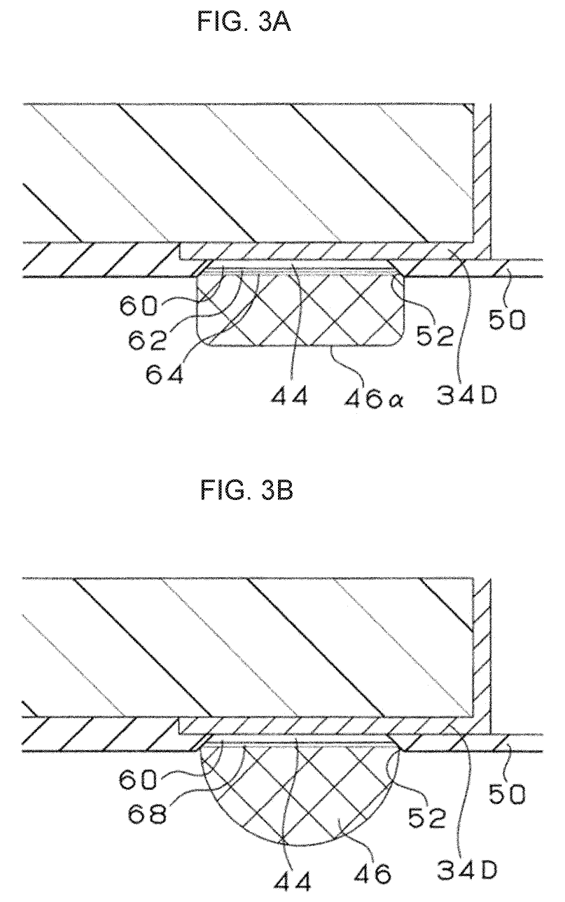

FIGS. 3A and 3B are each an enlarged view centered on a solder pad 44 provided in a conventional printed wiring board. As illustrated in FIG. 3A, solder paste (46α) is printed on the solder pad 44. The solder pad 44 is composed of a composite layer including three layers: a Ni layer 60, a Pd layer 62, and an Au layer 64, which are sequentially formed on a conductor circuit (34D). Next, a solder bump 46 is formed by reflow at 250 °C in a nitrogen atmosphere. During this reflow, the Pd layer 62 and the Au layer 64 diffuse toward the solder bump 46 side and disappear. As illustrated in FIG. 3B, a Cu-Ni-Sn alloy layer 68 composed of a Ni layer and solder composition metals is formed at an interface between the Ni layer 60 and the solder bump 46.

In Japanese Patent Application Laid-Open Publication No. 2006-114705, there is no recognition of defects arising from an Sn-Pd alloy formed by the diffusion of palladium contained in the Pd layer into the solder bump. That is, the palladium contained in the Sn-Pd alloy formed by the diffusion of palladium contained in the Pd layer into the solder bump may segregate in the Sn-Pd alloy. When the palladium contained in the Sn-Pd alloy segregates in the Sn-Pd alloy, the solder that melts after reflow does not melt uniformly. As a result, a problem arises in that, even when the Sn-Pd alloy in which palladium has segregated is reflowed, the solder bump after reflow does not have a rounded surface, and thus, the solder bump does not have an overall uniform spherical shape.

A printed wiring board according to an embodiment of the present invention has solder bumps in which, even when a protective film of a conductor layer provided in the printed wiring board contains palladium (Pd) such as Ni-Pd or Ni-Pd-Au, by preventing the palladium from segregating in the solder bumps, the palladium is uniformly melted into the solder bumps by reflow, and the solder bumps after reflow have a uniform spherical surface shape and a uniform height.

A printed wiring board according to an embodiment of the present invention includes: a conductor layer exposed from a solder resist layer opening formed in a solder resist layer that is formed so as to cover an insulating layer and the conductor layer, which are positioned as outermost layers of the printed wiring board; a Ni layer formed on a surface of the conductor layer; an alloy layer formed on a surface of the Ni layer; and a solder bump layer formed on a surface of the alloy layer. The solder bump layer contains an Sn-Pd alloy having a Pd content of 0.5 at% or less.

Further, a method for manufacturing a printed wiring board according to an embodiment of the present invention includes: forming a conductor layer on a resin insulating layer positioned as an outermost layer of the printed wiring board; forming a solder resist layer so as to cover the resin insulating layer and the conductor layer; exposing the conductor layer by forming a solder resist layer opening in the solder resist layer; forming a Ni layer on a surface of the conductor layer; forming a Pd layer on a surface of the Ni layer; forming a solder paste layer on a surface of the Pd layer; and reflowing a composite layer including the Ni layer and the Pd layer together with the solder paste layer. The Pd layer has a thickness of 0.01 to 0.03 μm.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
an outermost resin insulating layer;
a conductor layer formed on the outermost resin insulating layer;
a solder resist layer formed on the outermost resin insulating layer such that the solder resist layer is covering the conductor layer;
a Ni layer formed on a surface of a portion of the conductor layer such that the solder resist layer has an opening exposing the portion of the conductor layer;
an alloy layer formed on a surface of the Ni layer such that the alloy layer is positioned in the opening formed in the solder resist layer; and
a solder bump layer formed on a surface of the alloy layer such that the solder bump layer comprises an Sn-Pd alloy having a Pd content of 0.5 at% or less.

2. The printed wiring board according to claim 1, wherein the solder bump layer is formed by a process comprising forming a composite layer comprising the Ni layer and a Pd layer formed on the surface of the Ni layer and reflowing a solder paste layer formed on the alloy layer such that Pd in the Pd layer diffuses into the solder paste layer and that the solder bump layer comprising the Sn-Pd alloy having the Pd content of 0.5 at% or less is formed on the surface of the alloy layer.

3. The printed wiring board according to claim 2, wherein the solder bump layer is formed such that the Pd is uniformly diffused within the solder bump layer.

4. The printed wiring board according to claim 1, wherein the solder bump layer is formed such that a main component of the solder bump layer is Sn.

5. The printed wiring board according to claim 2, wherein a thickness of the Pd layer in the composite layer is in a range of 0.01 to 0.03 μm.

6. The printed wiring board according to claim 1, wherein the solder bump layer is formed such that the Pd content in the Sn-Pd alloy is in a range of 0.01 at% to 0.5 at%.

7. The printed wiring board according to claim 1, wherein the Ni layer has a thickness in a range of 1.5 to 3.0 μm.

8. The printed wiring board according to claim 1, wherein the alloy layer has a thickness in a range of 1.0 to 2.5 μm.

9. The printed wiring board according to claim 7, wherein the alloy layer has a thickness in a range of 1.0 to 2.5 μm.

10. The printed wiring board according to claim 1, wherein the alloy layer comprises an alloy comprising Ni and Sn.

11. The printed wiring board according to claim 4, wherein the solder bump layer is formed such that the Pd content in the Sn-Pd alloy is in a range of 0.01 at% to 0.5 at%.

12. The printed wiring board according to claim 4, wherein the Ni layer has a thickness in a range of 1.5 to 3.0 μm.

13. The printed wiring board according to claim 4, wherein the alloy layer has a thickness in a range of 1.0 to 2.5 μm.

14. The printed wiring board according to claim 12, wherein the alloy layer has a thickness in a range of 1.0 to 2.5 μm.

15. The printed wiring board according to claim 4, wherein the alloy layer comprises an alloy comprising Ni and Sn.

16. The printed wiring board according to claim 8, wherein the alloy layer comprises an alloy comprising Ni and Sn.

17. A method for manufacturing a printed wiring board, comprising:
forming an outermost resin insulating layer;
forming a conductor layer on the outermost resin insulating layer;
forming a solder resist layer on the outermost resin insulating layer such that the solder resist layer covers the conductor layer;
forming an opening in the solder resist layer such that the opening exposes a portion of the conductor layer;
forming a Ni layer on a surface of the portion of the conductor layer such that the Ni layer is positioned in the opening formed in the solder resist layer;
forming a Pd layer on a surface of the Ni layer such that the Pd layer is positioned in the opening formed in the solder resist layer; and
forming a solder bump layer on a surface of an alloy layer such that the solder bump layer comprises an Sn-Pd alloy having a Pd content of 0.5 at% or less,
wherein the forming the solder bump layer includes forming a solder paste layer on a composite layer comprising the Ni layer and the Pd layer and reflowing the solder paste layer formed on the composite layer such that Pd in the Pd layer diffuses into the solder paste layer and that the solder bump layer comprising the Sn-Pd alloy having the Pd content of 0.5 at% or less is formed on the surface of the alloy layer.

18. The method for manufacturing a printed wiring board according to claim 7, wherein the Pd layer in the composite layer has a thickness in a range of 0.01 to 0.03 μm, and the solder bump layer is formed such that a main component of the solder bump layer is Sn.

19. The method for manufacturing a printed wiring board according to claim 17, wherein the composite layer includes an Au layer formed on a surface of the Pd layer.

20. The method for manufacturing a printed wiring board according to claim 18, wherein the composite layer includes an Au layer formed on a surface of the Pd layer.
